(19) United States
(12) Patent Application Publication
(10) Pub. No.: US 2026/0140453 A1
(43) Pub. Date: May 21, 2026

(54) MULTI AXES MOTION MECHANISM ENABLING MULTIPLE OPTICAL COLUMNS METROLOGY SYSTEM

(71) Applicant: KLA Corporation, Milpitas, CA (US)

(72) Inventors: Ohad Bachar, Timrat (IL); Izhar Agam, Sarid (IL); Roei Leen, Haifa (IL); Omri Malik, Yokneam-illit (IL); Arkady Simkin, Yokneam Ilit (IL); Yoram Uziel, Yodfat (IL)

(21) Appl. No.: 19/092,526

(22) Filed: Mar. 27, 2025

Related U.S. Application Data
(60) Provisional application No. 63/722,590, filed on Nov. 19, 2024.

(51) Int. Cl. G03F 7/00

(52) U.S. Cl. CPC G03F 7/706845; G03F 7/706837; G03F 7/706851

(57) ABSTRACT

The system includes a stage configured to support a workpiece and a plurality of optical heads arranged above the stage. Each optical head includes a camera configured to capture a first image of one of a plurality of targets defined on a surface of the workpiece positioned along an optical axis of the camera and a motion mechanism configured to translate the optical head along three axes relative to the stage and rotate the optical head along two axes orthogonal to the optical axis. For each optical head, a processor determines a corrective movement of the optical head based on a misalignment of the optical axis of the camera relative to the target in a first image of the target captured by the camera, and sends instructions to the motion mechanism to move the optical head according to the corrective movement to align the optical axis with the target.

### CROSS-REFERENCE TO RELATED APPLICATIONS

This application claims priority to the provisional patent application filed Nov. 19, 2024, and assigned U.S. App. No. 63/722,590, the entire disclosure of which is hereby incorporated herein by reference.

### FIELD OF THE DISCLOSURE

This disclosure relates to semiconductor inspection and metrology systems and, more particularly, to multi-column inspection and metrology systems.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a semiconductor workpiece (e.g., wafer, substrate, display panel, etc.) using a large number of fabrication processes to form various features and multiple levels of the semiconductor devices. For example, lithography is a semiconductor fabrication process that involves transferring a pattern from a reticle to a photoresist arranged on a semiconductor workpiece. Additional examples of semiconductor fabrication processes include, but are not limited to, chemical-mechanical polishing (CMP), etch, deposition, and ion implantation. Multiple semiconductor devices may be fabricated in an arrangement on a single semiconductor workpiece that are separated into individual semiconductor devices.

Inspection processes are used at various steps during semiconductor manufacturing to detect defects on workpieces to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

Metrology processes are also used at various steps during semiconductor manufacturing to monitor and control the process. Metrology processes are different than inspection processes in that, unlike inspection processes in which defects are detected on workpieces, metrology processes are used to measure one or more characteristics of the workpieces that cannot be determined using existing inspection tools. Metrology processes can be used to measure one or more characteristics of workpieces such that the performance of a process can be determined from the one or more characteristics. For example, metrology processes can measure a dimension (e.g., line width, thickness, etc.) of features formed on the workpieces during the process. In addition, if the one or more characteristics of the workpieces are unacceptable (e.g., out of a predetermined range for the characteristic(s)), the measurements of the one or more characteristics of the workpieces may be used to alter one or more parameters of the process such that additional workpieces manufactured by the process have acceptable characteristic(s).

A semiconductor workpiece may include hundreds or thousands of regions of interest (i.e., targets) that may be monitored by inspection or metrology processes during semiconductor manufacturing. Typical inspection and metrology systems have a single optical head that is moved and stopped to align with each target of the workpiece to perform inspection or measurement. As the number of targets increases, the system throughput decreases due to the additional time needed to move and stop at each target. While additional optical heads can be used to simultaneously capture images of different targets, only moving the stage relative to the optical heads can result in misalignment with the targets due to variations in the workpiece. In addition, thermal drifts can change the locations of each optical head even when firmly mounted above the wafer, which limits the effectiveness of using multiple optical heads.

Therefore, what is needed is an improved system with multi-column alignment.

### BRIEF SUMMARY OF THE DISCLOSURE

An embodiment of the present disclosure provides a system. The system may comprise a stage configured to support a workpiece. A plurality of targets may be defined on a surface of the workpiece. The system may further comprise a plurality of optical heads arranged above the stage. Each optical head may comprise a camera configured to capture a first image of one of the plurality of targets positioned along an optical axis of the camera and a motion mechanism configured to translate the optical head along three axes relative to the stage and rotate the optical head along two axes that are orthogonal to the optical axis. The system may further comprise a processor in electronic communication with the camera and motion mechanism of each optical head. For each optical head, the processor may be configured to receive the first image of the target captured by the camera. The processor may be further configured to determine a corrective movement of the optical head based on a misalignment of the optical axis of the camera relative to the target in the first image. The processor may be further configured to send instructions to the motion mechanism to move the optical head according to the corrective movement to align the optical axis with the target, such that the plurality of optical heads may be each independently aligned with one the plurality of targets of the workpiece.

In some embodiments, for each optical head, the misalignment of the optical axis of the camera relative to the target may comprise at least one of a translational misalignment, an angular misalignment, or a focus misalignment.

In some embodiments, for each optical head, the corrective movement may comprise a translation of the optical head to center the optical axis with a center of the target to correct for the translational misalignment.

In some embodiments, for each optical head, the corrective movement may comprise a rotation of the optical head to position the optical axis to be orthogonal to the target on the surface of the workpiece to correct for the angular misalignment.

In some embodiments, each optical head may further comprise an objective lens disposed in the optical axis. The motion mechanism of each optical head may comprise a linear actuator configured to translate the objective lens along the optical axis relative to the camera to adjust the focus of the camera with the target.

In some embodiments, for each optical head, the corrective movement may comprise a translation of the objective lens to correct for the focus misalignment.

In some embodiments, the motion mechanism of each optical head may comprise four X-linear bearings, including two upper X-linear bearings connected to an upper end of the optical head and two lower X-linear bearings connected to a lower end of the optical head. The motion mechanism of each optical head may further comprise an X-linear actuator connected a rear end of the optical head by an X-rotary bearing. The X-linear actuator may be configured to translate the optical head along an X axis guided by the four X-linear bearings. The motion mechanism of each optical head may further comprise four Z-linear actuators, including two upper Z-linear actuators connected to the two upper X-linear bearings by two upper rotary bearings and two lower Z-linear actuators connected to the two lower X-linear bearings by two lower rotary bearings. Cooperative movement of the two upper Z-linear actuators and the two lower Z-linear actuators may be configured to translate the optical head along a Z axis. Opposing movement of the two upper Z-linear actuators and the two lower Z-linear actuators may be configured to rotate the optical head about a pitch axis. The motion mechanism of each optical head may further comprise four Y-linear bearings, including two upper Y-linear bearings connected to the two upper Z-linear actuators and two lower Y-linear bearings connected to the two lower Z-linear actuators. The motion mechanism of each optical head may further comprise two Y-linear motors, including an upper Y-linear motor connected to the two upper Y-linear bearings and a lower Y-linear motor connected to the two lower Y-linear bearings. Cooperative movement of the two Y-linear motors may be configured to translate the optical head along a Y axis guided by the four Y-linear bearings. Opposing movement of the two Y-linear motors may be configured to rotate the optical head about a roll axis.

In some embodiments, the system may further comprise an upper support arranged above the plurality of optical heads. The two upper Y-linear bearings and the upper Y-linear motor of each motion mechanism may be connected to the upper support. The system may further comprise a lower support arranged below the plurality of optical heads. The two lower Y-linear bearings and the lower Y-linear motor of each motion mechanism may be connected to the lower support. The system may further comprise a vertical support connected to the upper support and the lower support. The X-linear actuator may be connected to the vertical support.

In some embodiments, the motion mechanism of each optical head may further comprise one or more linear encoders. The processor may be further configured to receive position signals from the one or more linear encoders from each of the plurality of optical heads. The processor may be further configured to determine relative locations of the plurality of optical heads based on the position signals. The processor may be further configured to determine the corrective movement of each optical head based on the misalignment of the optical axis of the camera of the optical head relative to the target and the relative locations of the plurality of optical heads.

In some embodiments, the plurality of optical heads may be arranged in a one-dimensional array above the stage.

In some embodiments, the plurality of optical heads may be arranged in a two-dimensional array above the stage.

In some embodiments, after the plurality of optical heads are independently aligned with the plurality of targets of the workpiece, the processor may be further configured to send instructions to the camera of each optical head to simultaneously capture a plurality of second images of the plurality of targets.

In some embodiments, the plurality of optical heads may include one fixed optical head and a plurality of movable optical heads. The stage may be further configured to move the workpiece relative to the one fixed optical head. The processor may be further configured to send instructions to the stage to move relative to the one fixed optical head to align the optical axis with one target, while the plurality of movable optical heads are independently aligned with the remaining targets of the workpiece.

In some embodiments, the one fixed optical head may further comprise an objective lens disposed in the optical axis. The motion mechanism of the one fixed optical head may comprise a linear actuator configured to translate the objective lens relative to the camera along the optical axis to adjust the focus of the camera with the target.

Another embodiment of the present disclosure provides a method. The method may comprise step A) of capturing, with cameras of a plurality of optical heads, a plurality of first images of a plurality of targets defined on a surface of a workpiece supported by a stage. Each first image may include one target positioned along an optical axis of the camera of one of the plurality of optical heads. The method may further comprise step B) of determining, with a processor, a corrective movement of one optical head based on a misalignment of the optical axis of the camera of the optical head relative to the target in the first image. The method may further comprise step C) of moving, with a motion mechanism, the optical head according to the corrective movement to align the optical axis with the target. The motion mechanism may be configured to translate the optical head along three axes relative to the stage and rotate the optical head along two axes that are orthogonal to the optical axis. The method may further comprise step D) of repeating steps B) and C) for each of the plurality of optical heads, such that the plurality of optical heads are each independently aligned with one of the plurality of targets of the workpiece.

In some embodiments, step B) may comprise determining whether the misalignment of the optical axis of the camera of the optical head relative to the target comprises at least one of a translational misalignment, an angular misalignment, or a focus misalignment. Step B) may further comprise determining the corrective movement of the optical head to correct for at least one of the translational misalignment, the angular misalignment, or the focus misalignment. In some embodiments, step C) may comprises at least one of: translating the optical head to center the optical axis with a center of the target to correct for the translational misalignment; rotating the optical head to position the optical axis to be orthogonal to the target on the surface of the workpiece to correct for the angular misalignment; or translating an objective lens of the optical head along the optical axis relative to the camera to correct for the focus misalignment.

In some embodiments, step B) may comprise receiving position signals from one or more linear encoders from each of the plurality of optical heads. Step B) may further comprise determining relative locations of the plurality of optical heads based on the position signals. Step B) may further comprise determining the corrective movement of the optical head based on a misalignment of the optical axis of the camera of the optical head relative to the target and the relative locations of the plurality of optical heads.

In some embodiments, the plurality of optical heads may include one fixed optical head and plurality of movable optical heads. Before step B), the method may further comprise moving the stage relative to the one fixed optical head to align the one fixed optical head with one target. Steps B) to D) may be performed to independently align the plurality of movable optical heads with the remaining targets of the workpiece.

In some embodiments, the method may further comprise step E) of simultaneously capturing, with the cameras of the plurality of optical heads, a plurality of second images of the plurality of targets.

### DESCRIPTION OF THE DRAWINGS

For a fuller understanding of the nature and objects of the disclosure, reference should be made to the following detailed description taken in conjunction with the accompanying drawings, in which:

FIG. 1 is a front view of a system according to an embodiment of the present disclosure;

FIG. 2 is a partial side view of the system of FIG. 1;

FIG. 3A is a detailed front view of a one optical head of the system of FIG. 1;

FIG. 3B is a detailed front view of the optical head of FIG. 3A, in which the optical head is translated in the X direction and an objective lens is translated in the Z direction;

FIG. 3C is a detailed front view of the optical head of FIG. 3A, in which the optical head is rotated about a pitch axis;

FIG. 4A is a detailed side view of three optical heads of the system of FIG. 2;

FIG. 4B is a detailed side view of the three optical heads of FIG. 4A, in which the optical heads are translated in the Y direction and the objective lenses are translated in the Z direction;

FIG. 4C is a detailed side view of the three optical heads of FIG. 4A, in which the optical heads are rotated about a roll axis;

FIG. 5 is a flowchart of a method according to an embodiment of the present disclosure;

FIG. 6 is a flowchart of a method according to another embodiment of the present disclosure;

FIG. 7 is a flowchart of a method according to another embodiment of the present disclosure;

FIG. 8 is a flowchart of a method according to another embodiment of the present disclosure; and

FIG. 9 is a flowchart of a method according to another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

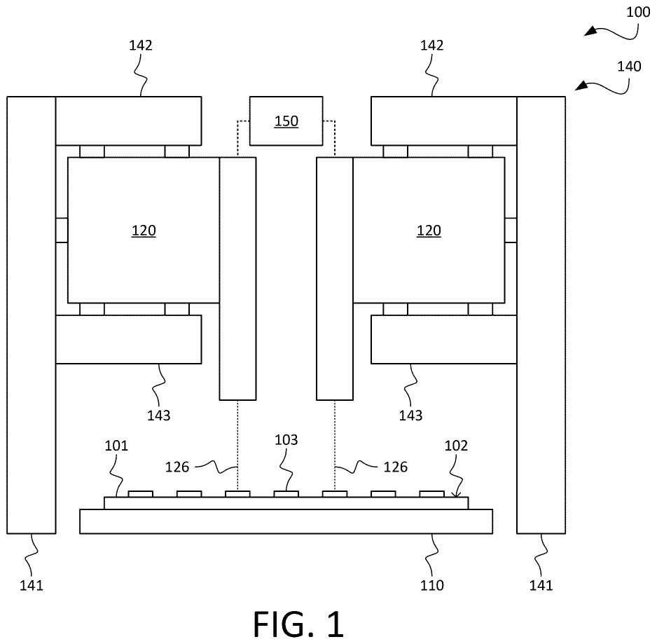

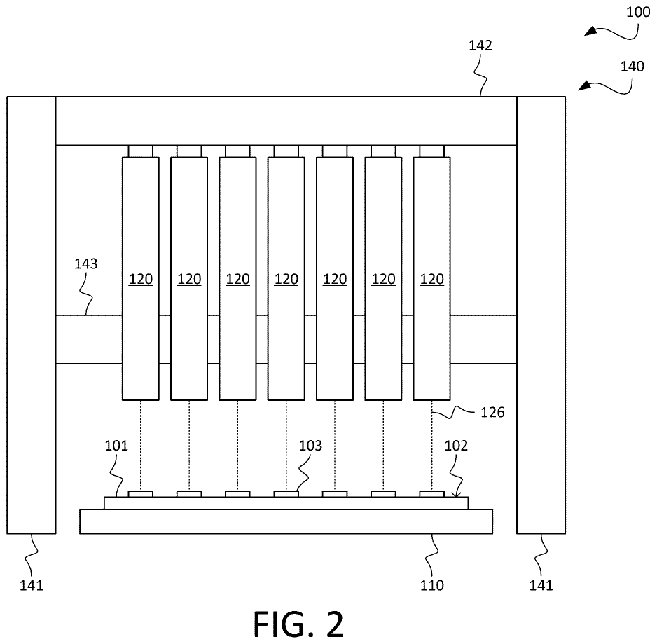

An embodiment of the present disclosure provides a system 100, as shown in FIGS. 1 and 2. The system 100 may be an optical inspection or metrology system configured to perform various measurements on a workpiece 101. The workpiece 101 may be, for example, a semiconductor wafer, substrate, printed-circuit board (PCB), integrated circuit (IC), flat panel display (FPD) or other type of workpiece. A plurality of targets 103 may be defined on a surface 102 of the workpiece 101. The plurality of targets 103 may be arranged in a regular (or irregular) array on the surface 102 of the workpiece 101. The plurality of targets 103 may include various features or patterns of the workpiece 101 to be measured by the system 100. For example, the plurality of targets 103 may include gratings, box-in-box, or other possible shapes that are added to chip design to enhance metrology features. In an instance, a target 103 may include a single or multiple lines for critical dimension (CD) metrology. Some targets 103 can include a combination of patterned shapes to enable thin film metrology, pattern uniformity, or others. Although the plurality of targets 103 are shown in FIGS. 1 and 2 as protruding from the surface 102 of the workpiece 101, each target 103 may have varying height or depth relative to the surface 102 of the workpiece 101. In addition, each target 103 may have an upper surface that is nonparallel to the surface 102 of the workpiece 101. The workpiece 101 may include hundreds or thousands of targets 103, depending on the type of workpiece and the features to be measured by the system 100.

The system 100 may comprise a stage 110. The stage 110 may be configured to support the workpiece 101. The stage 110 may include one or more motors or actuators configured to move the workpiece 101 in or more in plane directions (e.g., X-direction or Y-direction) or out of plane directions (e.g., Z-direction).

The system 100 may further comprise a plurality of optical heads 120 arranged above the stage 110. In some embodiments, the plurality of optical heads 120 may be arranged in a one-dimensional array above the stage 110. For example, two optical heads 120 are shown in a one-dimensional array in the X-direction in FIG. 1, and seven optical heads 120 are shown in a one-dimensional array in the Y-direction in FIG. 2. Alternatively, the plurality of optical heads 120 may be arranged in a two-dimensional array above the stage 110. For example, the combination of FIGS. 1 and 2 may illustrate a two-dimensional array of two rows of seven optical heads 120. The number of optical heads 120 may depend on the dimensions of each optical head 120 and the dimensions of the workpiece 101. In some embodiments, different rows of optical heads 120 may be oriented parallel to each other, so as to simultaneously capture perspectives of multiple targets 103. Alternatively, adjacent rows of optical heads 120 may be oriented 90 degrees relative to each other, such that one row of optical heads 120 faces down onto the stage 110 and the other row of optical heads 120 faces across the stage 110 from the side, so as to simultaneously capture two perspectives of the target 103. Other arrangements and numbers of optical heads 120 are possible and is not limited herein.

Each optical head 120 may comprise a camera 125. Each camera 125 may be a charge coupled device (CCD) camera, time delay integration (TDI) camera, or other type of sensor collects photons. Each camera 125 may be configured to capture a first image of one of the plurality of targets 103 positioned along an optical axis 126 of the camera 125. Accordingly, the plurality of optical heads 120 may be configured to simultaneously capture a plurality of images of a number of targets 103 of the workpiece 101 equal to the number of optical heads 120. Each optical head 120 may further comprise an objective lens 127 disposed in the optical axis 126. The camera 135 may be focused with the target 103 based on the position of the objective lens 127 along the optical axis 126. Other optical elements may be included in each optical head 120, disposed in the optical axis 126, to affect image capturing by the camera 125.

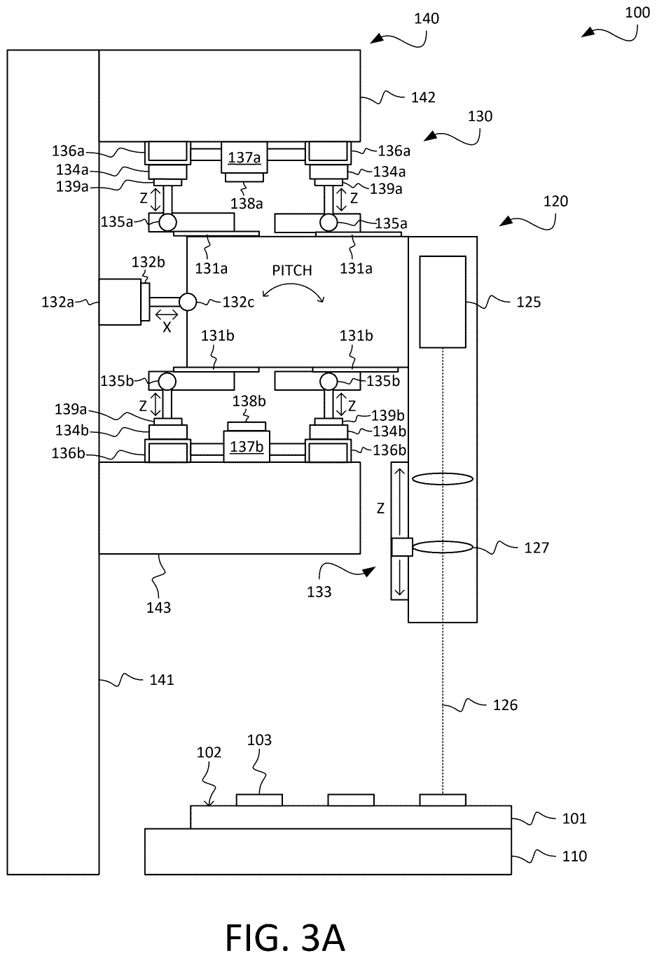

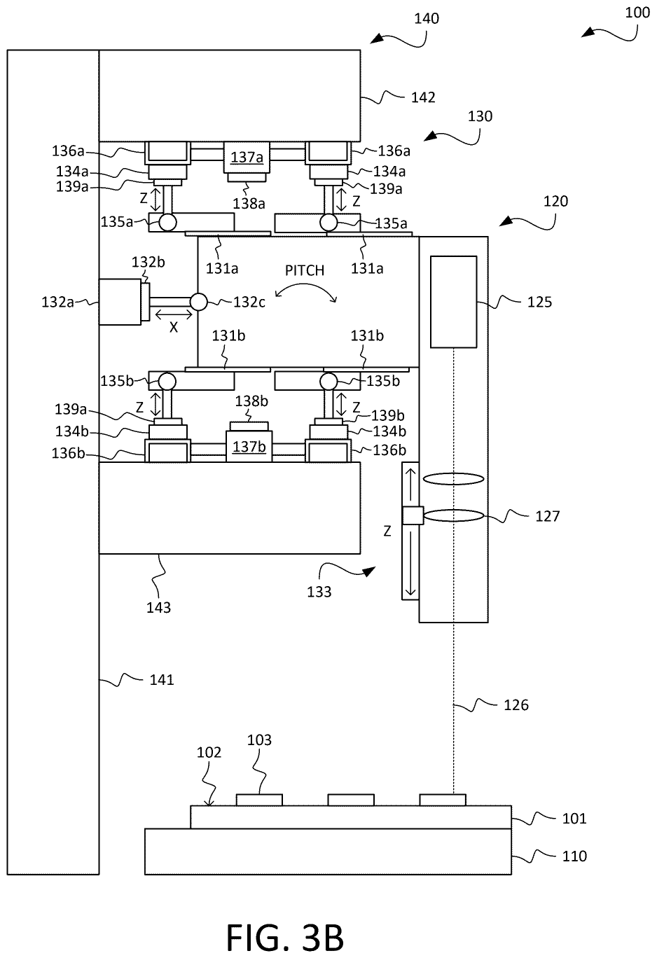

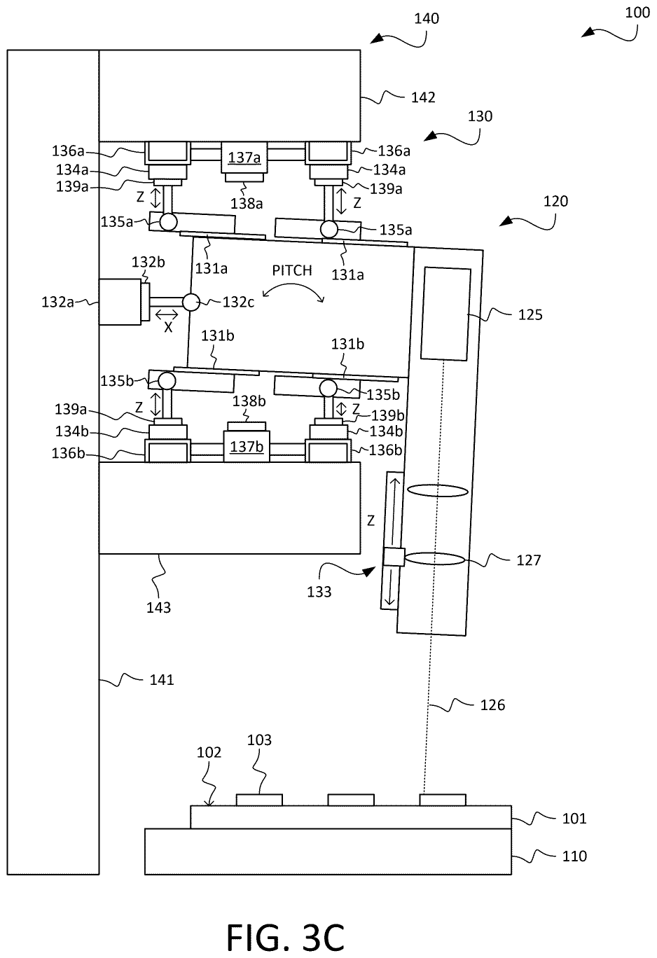

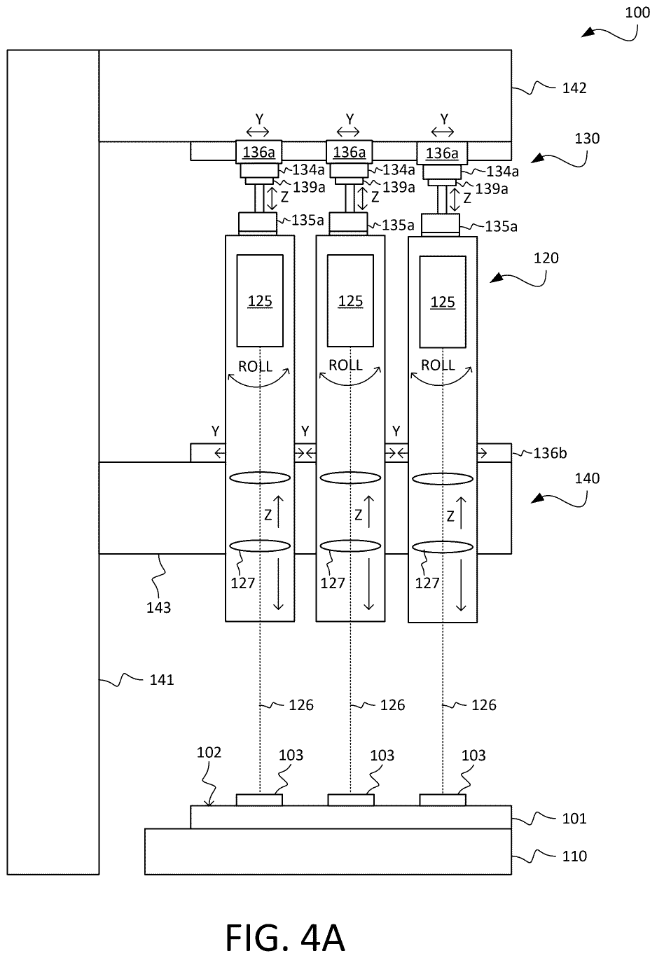

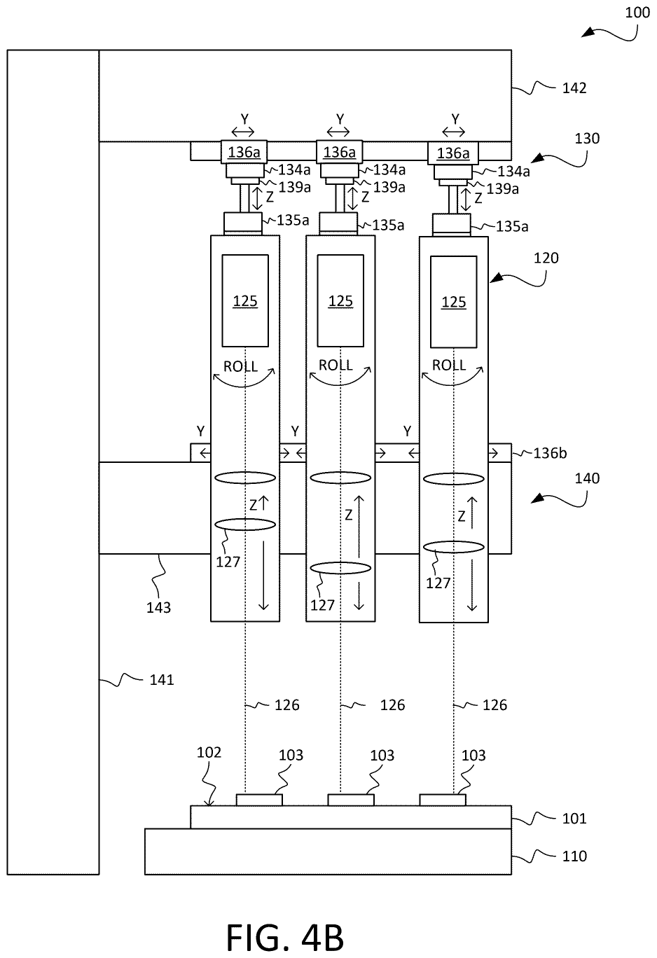

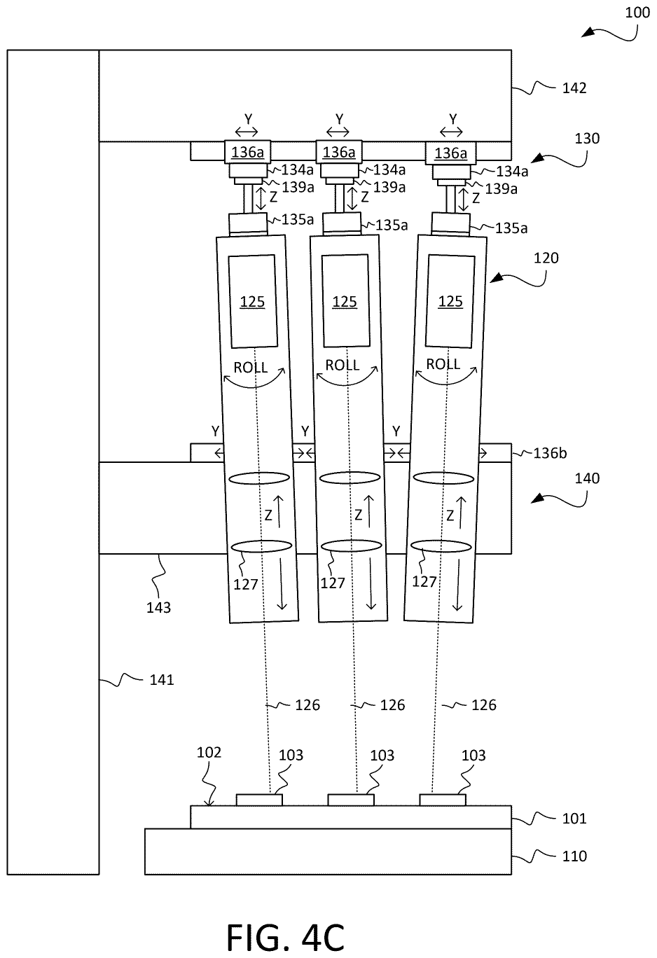

Each optical head 120 may further comprise a motion mechanism 130. The motion mechanism 130 may be configured to translate the optical head 120 along three axes relative to the stage 110 (e.g., X-axis, Y-axis, and Z-axis) and rotate the optical head 120 along two axes that are orthogonal to the optical axis 126 (e.g., a pitch axis and a roll axis). Accordingly, the plurality of optical heads 120 may be independently adjustable by each motion mechanism 130 to align the optical axis 126 of each optical head 120 with one of the targets 103 of the workpiece 101. The motion mechanism 130 may include various combinations of bearings, motors, and actuators configured to translate and rotate each optical head 120. FIGS. 3A to 3C and FIGS. 4A to 4C illustrate exemplarily elements of a motion mechanism 130 of the present disclosure.

Referring to FIG. 3A, the motion mechanism 130 may comprise four X-linear bearings, including two upper X-linear bearings 131a and two lower X-linear bearings 131b. The two upper X-linear bearings 131a may be connected to an upper end of the optical head 120, and the two lower X-linear bearings 131b may be connected to a lower end of the optical head 120. The motion mechanism 130 may further comprise an X-linear actuator 132a connected to a rear end of the optical head 120 by an X-rotary bearing 132c. The X-linear actuator 132a may be configured to translate the optical head 120 along an X-axis guided by the four X-linear bearings. For example, extending the X-linear actuator 132a may be configured to translate the optical head 120 along the X-axis from the position shown in FIG. 3A to the position shown in FIG. 3B. The X-linear actuator 132a may further extend or retract to positions other than the exemplary positions illustrated herein. Translation along the X-axis may move the optical head 120 in either direction with millimeter level adjustment (e.g., 10 to 20 mm). In some embodiments, a combination of motion of the stage 110 and the optical head 120 can be used to scan the workpiece 101 along the X-axis. The motion mechanism 130 may be configured to align the optical axis 126 of the camera 125 with a center of the target 103 by translating the optical head 120 along the X-axis. In some embodiments, aligning the optical axis 126 of the camera 125 with the center of the target 103 may allow the entire target 103 to be visible to the camera 125 for imaging.

The motion mechanism 130 may further comprise four Z-linear actuators, including two upper Z-linear actuators 134a and two lower Z-linear actuators 134b. The two upper Z-linear actuators 134a may be connected to the two upper X-linear bearings 131a by two upper rotary bearings 135a, and the two lower Z-linear actuators 134b may be connected to the two lower X-linear bearings 131b by two lower rotary bearings 135b. Cooperative movement of the two upper Z-linear actuators 134a and the two lower Z-linear actuators 134b may be configured to translate the optical head 120 along a Z-axis. For example, extending the two upper Z-linear actuators 134a while retracting the two lower Z-linear actuators 134b may cause the optical head 120 to translate down along the Z-axis from the position shown in FIG. 3A, and retracting the two upper Z-linear actuators 134a while extending the two lower Z-linear actuators 134b may cause the optical head 120 to translate up along the Z-axis from the position shown in FIG. 3A. The four Z-linear actuators may further extend or retract to positions other than the exemplary positions illustrated herein. The motion mechanism 130 may be configured to adjust a relative distance between the camera 125 and the target 103 along the Z-axis for coarse focus alignment (i.e., millimeter level adjustment, e.g., 10 to 20 mm). In some embodiments, the four Z-linear actuators may allow for nanometer level adjustment along the Z-axis.

Opposing movement of the two upper Z-linear actuators 134a and the two lower Z-linear actuators 134b may be configured to rotate the optical head 120 about a pitch axis. For example, extension of one of the two upper Z-linear actuators 134a and retraction of the other one of the two upper Z-linear actuators 134a with corresponding extension and retraction of the two lower Z-linear actuators 134b may cause the optical head 120 to rotate along the pitch axis from the position shown in FIG. 3A to the position shown in FIG. 3C. Rotation along the pitch axis may “tip” the optical head 120 in either direction with microradian level adjustment. The four Z-linear actuators may further extend or retract with opposing movements to positions other than the exemplary positions illustrated herein. The motion mechanism 130 may be configured to align the optical axis 126 of the camera 125 to be orthogonal to the target 103 by rotating the optical head 120 along the pitch axis.

The motion mechanism 130 may further comprise four Y-linear bearings, including two upper Y-linear bearings 136a and two lower Y-linear bearings 136b. The two upper Y-linear bearings 136a may be connected to the two upper Z-linear actuators 134a, and the two lower Y-linear bearings 136b may be connected to the two lower Z-linear actuators 134b. The motion mechanism 130 may further comprise two Y-linear motors, including an upper Y-linear motor 137a and a lower Y-linear motor 137b. The upper Y-linear motor 137a may be connected to the two upper Y-linear bearings 136a, and the lower Y-linear motor 137b may be connected to the two lower Y-linear bearings 136b. Cooperative movement of the upper Y-linear motor 137a and the lower Y-linear motor 137b may be configured to translate the optical head 120 along a Y-axis guided by the four Y-linear bearings. For example, movement of the upper Y-linear motor 137a and the lower Y-linear motor 137b to the right or left in FIG. 4A may cause corresponding movements of the two upper Y-linear bearings 136a and the two lower Y-linear bearings 136b to translate the optical head 120 along the Y-axis from the position(s) shown in FIG. 4A to the position(s) shown in FIG. 4B. The Y-linear motors may further move to positions other than the exemplary positions illustrated herein. Translation along the Y-axis may move the optical head 120 in either direction with millimeter level adjustment (e.g., 10 to 50 mm). In some embodiments, the two Y-linear motors may allow for nanometer level adjustment along the Y-axis. The motion mechanism 130 may be configured to align the optical axis 126 of the camera 125 with a center of the target 103 by translating the optical head 120 along the Y-axis. In some embodiments, the two upper Y-linear bearings 136a and the two lower Y-linear bearings 136b of adjacent optical heads 120 may be connected or share the same fixed portion, while having separate movable portions to adjust the position of the respective optical heads 120 along the Y-axis.

Opposing movement of the upper Y-linear motor 137a and the lower Y-linear motor 137b may be configured to rotate the optical head about a roll axis. For example, movement of the upper Y-linear motor 137a to the left and opposite movement of the lower Y-linear motor 137b to the right may cause corresponding movements of the two upper Y-linear bearings 136a and the two lower Y-linear bearings 136b to rotate the optical head 120 along the roll axis from the position(s) shown in FIG. 4A to the position(s) shown in FIG. 4C. Rotation along the roll axis may “tilt” the optical head 120 in either direction with microradian level adjustment. The two Y-linear actuators may further move in opposite directions to positions other than the exemplary positions illustrated herein. The motion mechanism 130 may be configured to align the optical axis 126 of the camera 125 to be orthogonal to the target 103 by rotating the optical head 120 along the roll axis.

The motion mechanism 130 may further comprise a micro Z-linear actuator 133 configured to translate the objective lens 127 along the optical axis 126 relative to the camera 125. Accordingly, the motion mechanism 130 may be configured to adjust a relative position of the objective lens 127 between the camera 125 and the target 103 along the Z-axis for fine focus alignment (i.e., nanometer level adjustment).

Although the motion mechanism 130 is described with exemplary linear motors, linear actuators, and rotary bearings, the motion mechanism 130 may comprise other elements configured to translate and rotate each optical head 120 as disclosed herein. For example, the motion mechanism 130 may include air bearings, mechanical bearings, or magnetic bearings to implement the degrees of freedom of the movable elements. The motion mechanism 130 may include linear motors or actuators, planar motors, piezo crystal motors (e.g., walking piezo or expanded crystal), voice coils, or gear driven motors (e.g., rack and pinion design) to implement translation and rotation of the optical heads 120. In some embodiments, the assemblies of the elements of the motion mechanism 130 may vary from the exemplary assemblies described herein (i.e., stacked from outside to inside as Y-Z-X). For example, the motion mechanism 130 may be stacked outside to inside as Y-X-Z, X-Y-Z, X-Z-Y, Z-Y-X, or Z-X-Y, which may each implement similar movements of the optical heads 120.

The system 100 may further comprise a support structure 140. The support structure 140 may be configured to support the plurality of optical heads 120 above the stage 110. The support structure 140 may comprise a vertical support 141, and upper support 142, and a lower support 143. The upper support 142 may be arranged above the plurality of optical heads 120. The two upper Y-linear bearings 136a and the upper Y-linear motor 137a of each motion mechanism 130 may be connected to the upper support 142. The lower support 143 may be arranged below the plurality of optical heads 120. The two lower Y-linear bearings 136b and the lower Y-linear motor 137b may be connected to the lower support 143. The vertical support 141 may be connected to the upper support 142 and the lower support 143. The X-linear actuator 132a may be connected to the vertical support 141. Accordingly, each optical head 120 may be connected to the support structure 140 by the motion mechanism 130 with high stiffness for stable support for the camera 125 when capturing images in various positions.

The system 100 may further comprise a processor 150. The processor 150 may include a microprocessor, a microcontroller, or other devices. The processor 150 may be coupled to the components of the system 100 in any suitable manner (e.g., via one or more transmission media, which may include wired and/or wireless transmission media) such that the processor 150 can receive output. The processor 150 may be configured to perform a number of functions using the output. An inspection tool can receive instructions or other information from the processor 150. The processor 150 optionally may be in electronic communication with another inspection tool, a metrology tool, a repair tool, or a review tool (not illustrated) to receive additional information or send instructions.

The processor 150 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 150 may be disposed in or otherwise part of the system 100 or another device. In an example, the processor 150 may be part of a standalone control unit or in a centralized quality control unit. Multiple processors 150 may be used, defining multiple subsystems of the system 100.

The processor 150 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 150 to implement various methods and functions may be stored in readable storage media, such as a memory.

If the system 100 includes more than one subsystem, then the different processors 150 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 150 may be configured to perform a number of functions using the output of the system 100 or other output. For instance, the processor 150 may be configured to send the output to an electronic data storage unit or another storage medium. The processor 150 may be further configured as described herein.

The processor 150 may be configured according to any of the embodiments described herein. The processor 150 also may be configured to perform other functions or additional steps using the output of the system 100 or using images or data from other sources.

The processor 150 may be communicatively coupled to any of the various components or sub-systems of system 100 in any manner known in the art. Moreover, the processor 150 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 150 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 150 (or computer subsystem) or, alternatively, multiple processors 150 (or multiple computer subsystems). Moreover, different sub-systems of the system 100 may include one or more computing or logic systems. Therefore, the above description should not be interpreted as a limitation on the present disclosure but merely an illustration.

The processor 150 may be in electronic communication with the stage 110. For example, the processor 150 may be configured to send instructions to the one or more motors or actuators of the stage 110 to move the stage 110 supporting the workpiece 101 relative to the plurality of optical heads 120.

The processor 150 may be in electronic communication with the camera 125 of each of the plurality of optical heads 120. For example, the processor 150 may be configured to send instructions to each camera 125 to capture respective images of targets 103 of the workpiece 101 that are positioned along the optical axis 126 of each camera 125. For each optical head 120, the processor 150 may be configured to receive a first image of the target 103 captured by the camera 125. The processor 150 may be configured to locate the target 103 in each first image using an image processing algorithm. For example, the processor 150 may identify the edges of the target 103 and/or the center of the target 103 in the first image. The processor 150 may be further configured to determine whether there is a misalignment of the optical axis 126 of the camera 125 relative to the target 103 based on the first image of the target 103. The misalignment may comprise at least one of a translational misalignment, and angular misalignment, or a focus misalignment. A translational misalignment may be present where the optical axis 126 of the camera 125 is offset from a center of the target 103 along the X-axis and/or the Y-axis. An angular misalignment may be present where the optical axis 126 of the camera 125 is at an oblique angle (i.e., not orthogonal) relative to the target 103 along the pitch axis and/or the roll axis. A focus misalignment may be present where the position of the objective lens 127 along the optical axis 126 along the Z-axis causes the target to be out of focus. Any one target 103 of the plurality of targets 103 may have translational misalignment (in one or more directions), angular misalignment (in one or more directions), focus misalignment, or any combination thereof. Among the plurality of targets 103, the types and degrees of misalignment may vary. Accordingly, the processor 150 may independently analyze each first image to determine the individual misalignment of each optical head 120 with the respective target 103.

For each optical head 120, the processor 150 may be further configured to determine a corrective movement of the optical head 120 based on the misalignment of the optical axis 126 of the camera 125 relative to the target 103 in the first image. The corrective movement may include one or more movements of the optical to head to correct for different types of misalignments. For example, the corrective movement may comprise a translation of the optical head 120 (i.e., along the X-axis and/or Y-axis) to center the optical axis 126 with the center of the target 103 to correct for translational misalignment. The corrective movement may comprise a rotation of the optical head 120 to position the optical axis 126 to be orthogonal to the target 103 on the surface 102 of the workpiece 101 to correct for angular misalignment. The corrective movement may comprise a translation of the objective lens 127 along the optical axis 126 relative to the camera 125 to correct for focus misalignment. For each optical head 120, the corrective movement may include any types or degrees of translation or rotation to correct for the individual misalignment of the optical head 120 relative to the target 103. Accordingly, the processor 150 may independently determine the appropriate corrective movements of each optical head 120 to correct for the individual misalignments.

The processor 150 may be in electronic communication with the motion mechanism 130 of each optical head 120. For example, the processor 150 may be configured to send instructions to each motion mechanism 130 to move each optical head 120 according to the corrective movement to align the optical axis 126 with the target 103. The instructions may include, for example, various cooperative or opposing movements of the X-linear actuator 132a, the two upper Z-linear actuators 134a, the two lower Z-linear actuators 134b, the upper Y-linear motor 137a, and the lower Y-linear motor 137b in order to translate the optical head 120 along the X-axis, Y-axis, and/or Z-axis, and/or to rotate the optical head 120 along the pitch axis or the roll axis, as described above. Accordingly, each motion mechanism 130 may may move its respective optical head 120 such that the plurality of optical heads 120 are each independently aligned with one of the targets 103 of the workpiece 101.

After the plurality of optical heads 120 are independently aligned with the plurality of targets 103 of the workpiece 101, the processor 150 may be further configured to send instructions to the camera 125 of each optical head 120 to simultaneously capture a plurality of second images of the plurality of targets 103. Compared to each first image, each second image may include a target 103 that is aligned with the optical axis 126 of the camera 125, which can enable more accurate measurements for inspection and metrology processes. After capturing the plurality of second images of the plurality of targets 103, the processor 150 may be configured to send instructions to the one or more motors or actuators of the stage 110 to move the workpiece 101 relative to the plurality of optical heads 120, such that different targets 103 of the plurality of targets are now positioned along the optical axis 126 of each camera 125. The processor 150 may repeat the steps described above to correct the alignment of each optical head 120 for inspection of these different targets 103. Accordingly, the system 100 may be used to quickly and efficiently perform measurements of the plurality of targets 103 of the workpiece 101 through simultaneous measurements with the plurality of optical heads 120.

In some embodiments, the motion mechanism 130 of each optical head 120 may further comprise one or more linear encoders configured to track movement of the motion mechanism 130 relative to the X-axis, Y-axis, and/or Z-axis, so as to track the relative positions of each optical head 120 and avoid collisions. For example, the motion mechanism 130 of each optical head 120 may further comprise an X-linear encoder 132b. The X-linear encoder 132b may be connected to the X-linear actuator 132a, and may be configured to generate position signals corresponding to the movement of the optical head 120 along the X-axis. The motion mechanism 130 of each optical head 120 may further comprise an upper Y-linear encoder 138a and a lower Y-linear encoder 138b. The upper Y-linear encoder 138a may be connected to the upper Y-linear motor 137a, and the lower Y-linear encoder 138b may be connected to the lower Y-linear motor 137b. The upper Y-linear encoder 138a and the lower Y-linear encoder 138b may be configured to generate position signals corresponding to movement of the optical head 120 along the Y-axis. The motion mechanism 130 of each optical head 120 may further comprise two upper Z-linear encoders 139a and two lower Z-linear encoders 139b. The two upper Z-linear encoders 139a may be connected to the two upper Z-linear actuators 134a, and the two lower Z-linear encoders 139b may be connected to the two lower Z-linear actuators 134b. The two upper Z-linear encoders 139a and the two lower Z-linear encoders 139b may be configured to generate position signals corresponding to the movement of the optical head 120 along the Z-axis.

The processor 150 may be configured to receive the position signals from the X-linear encoder 132 b, the upper Y-linear encoder 138a, the lower Y-linear encoder 138b, the two upper Z-linear encoders 139a and the two lower Z-linear encoders 139b of each of the plurality of optical heads 120. The processor 150 may be further configured to determine relative locations of the plurality of optical heads 120 based on the position signals. For example, as shown in FIG. 4A, the plurality of optical heads 120 may be arranged close together along the Y-axis. Accordingly, some corrective movements of the optical head 120 that include translation along the Y-axis or rotation along the roll axis may cause collisions between adjacent optical heads 120. To avoid collisions, the processor 150 may determine the corrective movement of each optical head 120 based on the misalignment of the optical axis 126 of the camera 125 relative to the target 103 and the relative locations of the plurality of optical heads 120. Thus, although the processor 150 may individually determine the corrective movement of each optical head 120 to align the optical axis 126 of the camera 125 with the target 103, the processor 150 may also consider the relative positions of the other optical heads 120 to ensure compatibility of the positions.

In some embodiments, the plurality of optical heads 120 may comprise one fixed optical head and a plurality of movable optical heads. The processor 150 may be configured to send instructions to the one or more motors or actuators of the stage 110 to move the stage 110 relative to the one fixed optical head to align its optical axis 126 with one target 103, while the plurality of movable optical heads are independently aligned with the remaining targets 103 of the workpiece 101. By first aligning one optical head 120 with a target 103 using the stage 110, it may simplify the process of aligning the remaining optical heads 120 with other targets 103. The one fixed optical head may be preset among the plurality of optical heads 120, or the processor 150 may determine one of the plurality of optical heads 120 as the fixed optical head based on ease of alignment of the optical axis 126 with the target 103 or the ability to realign the other optical heads 120. Accordingly, the one fixed optical head may have the same structure as the movable optical heads (i.e., the fixed optical head may also include a motion mechanism 130 configured to move the fixed optical head in the same directions, these movements just may not be used in the alignment process). Alternatively, the one fixed optical head may have a motion mechanism 130 that only includes a micro Z-linear actuator 133 configured to translate the objective lens 127 relative to the camera 125 along the optical axis 126 to adjust the focus of the camera 125 with the target 103, thereby omitting the other elements of the motion mechanism 130 present in the movable optical heads.

With the system 100, multiple optical heads 120 can be independently aligned with a plurality of targets 103 of the workpiece 101 in order to perform measurements of multiple targets 103 simultaneously, which improves efficiency and throughput compared a system with a single optical head, and also improves accuracy compared to a system with multiple fixed optical heads.

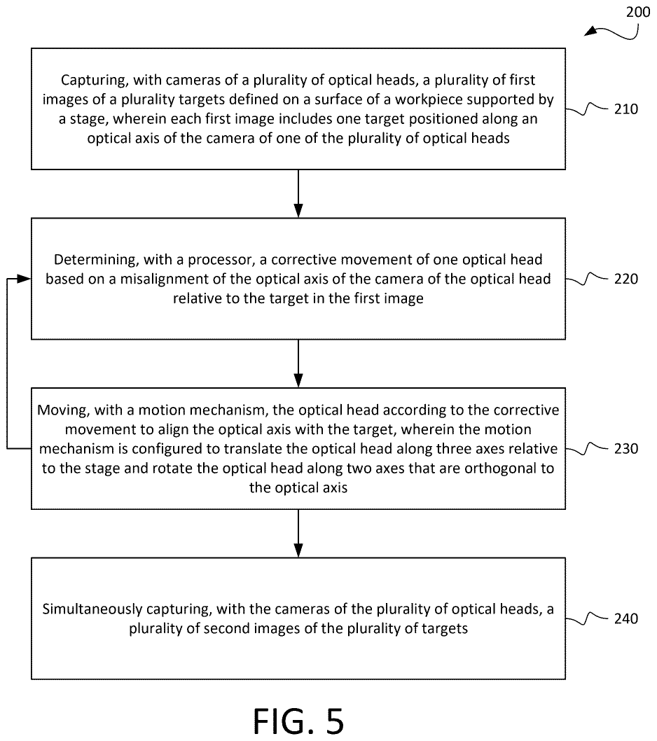

Another embodiment of the present disclosure provides a method 200. As shown in FIG. 5, the method 200 may comprise the following steps.

At step 210, cameras of a plurality of optical heads capture a plurality of first images of a plurality of targes defined on a surface of a workpiece supported by a stage. Each first image may include one target positioned along an optical axis of the camera of one of the optical heads.

At step 220, a processor determines a corrective movement of one optical head based on a misalignment of the optical axis of the camera of the optical head relative to the target in the first image.

At step 230, a motion mechanism of the optical head moves the optical head according to the corrective movement to align the optical axis with the target. The motion mechanism may be configured to translate the optical head along three axes relative to the stage and rotate the optical head along two axes that are orthogonal to the optical axis.

After repeating steps 220 and 230 for each optical head, at step 240, the cameras of the plurality of optical heads simultaneously capture a plurality of second images of the plurality of targets. In some embodiments, the processor may verify the alignment of each optical head relative to the target in each second image. If any misalignment is present, steps 220 and 230 may be repeated, until each optical head is aligned with its respective target.

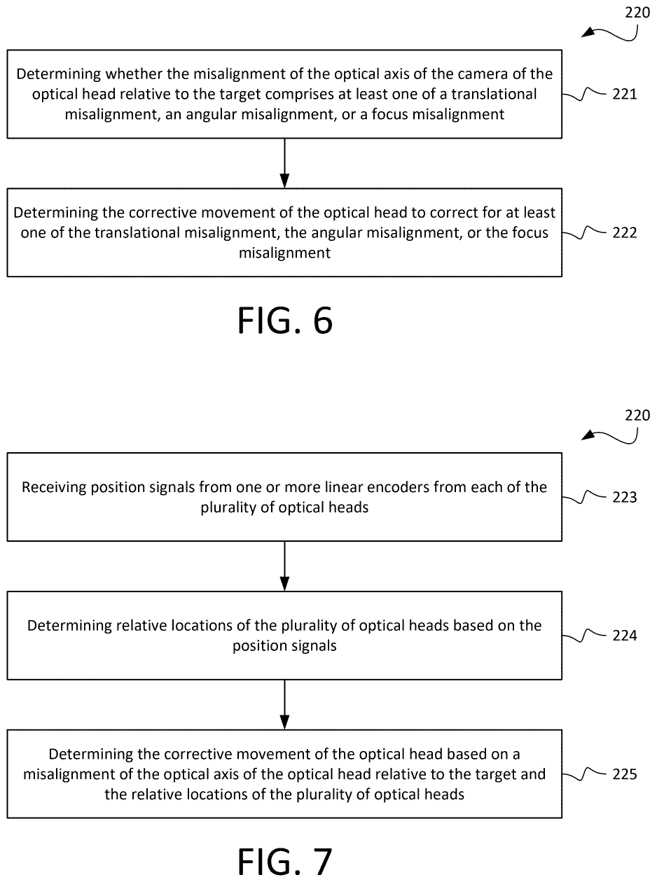

In some embodiments, step 220 may comprise the following steps shown in FIG. 6.

At step 221, the processor determines whether the misalignment of the optical axis of the camera of the optical head relative to the target comprises at least one of a translational misalignment, and angular misalignment, or a focus misalignment.

At step 222, the processor determines the corrective movement of the optical head to correct for at least one of the translational misalignment, the angular misalignment, or the focus misalignment.

In some embodiments, step 220 may comprise (or further comprise) the following steps shown in FIG. 7.

At step 223, the processor receives position signals from one or more linear encoders from each of the plurality of optical heads. The one or more linear encoders may be configured to generate position signals corresponding to movement of each optical head relative o the X-axis, Y-axis, and/or Z-axis.

At step 224, the processor determines relative locations of the plurality of optical heads based on the position signals.

At step 225, the processor determines the corrective movement of the optical head based on a misalignment of the optical axis of the camera of the optical head relative to the target and the relative locations of the plurality of optical heads.

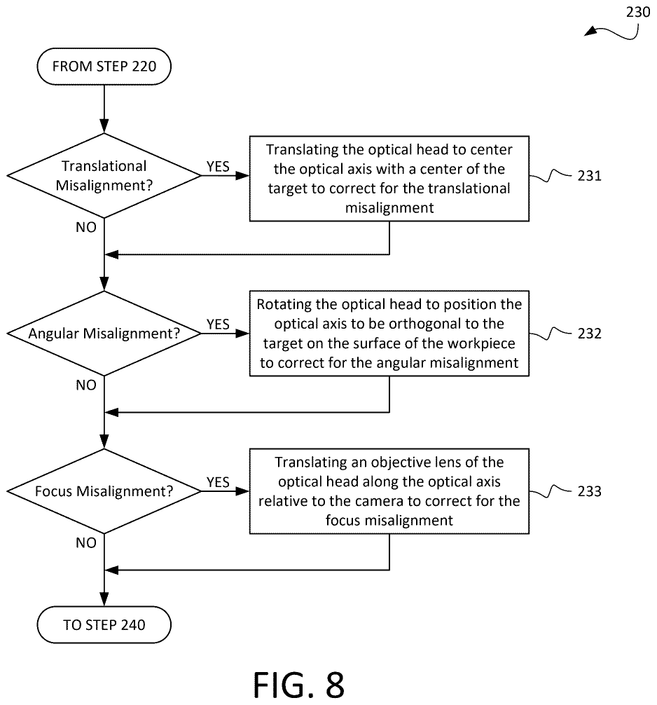

In some embodiments, step 230 may comprise the following steps shown in FIG. 8.

If it is determined in step 220 that the misalignment of the optical axis of the camera of the optical head relative to the target comprises a translational misalignment, at step 231, the motion mechanism translates the optical head to center the optical axis with a center of the target to correct for the translational misalignment.

If it is determined in step 220 that the misalignment of the optical axis of the camera of the optical head relative to the target comprises a rotational misalignment, at step 232, the motion mechanism rotates the optical head to position the optical head to be orthogonal to the target on the surface of the workpiece to correct for the angular misalignment.

If it is determined in step 220 that the misalignment of the optical axis of the camera of the optical head relative to the target comprises a focus misalignment, at step 233, the motion mechanism translates an objective lens of the optical head along the optical axis relative to the camera to correct for the focus misalignment.

In some embodiments, step 230 may include any one of steps 231, 232, or 233, each of steps 231, 232, and 233, or any combination thereof, depending on the type(s) of misalignment of the optical axis of the camera of the optical head relative to the target.

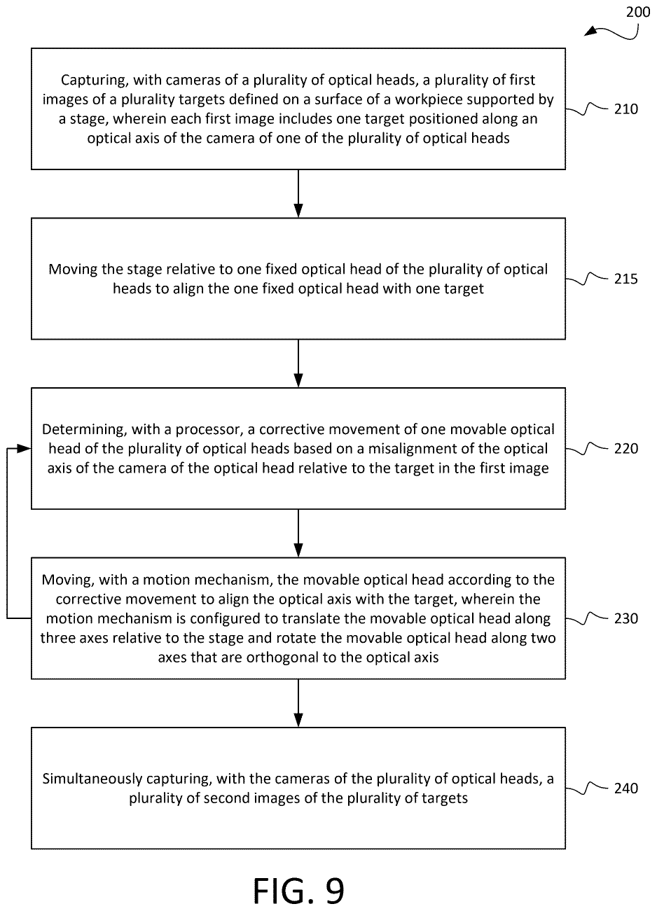

In some embodiments, the plurality of optical heads may include one fixed optical head, with the remaining optical heads being movable optical heads. Accordingly, the method 200 may further comprise step 215, as shown in FIG. 9. At step 215, the stage is moved relative to one fixed optical head of the plurality of optical heads to align the one fixed optical head with one target of the plurality of targets. Subsequently, steps 220 and 230 may be performed to align each of the movable optical heads of the plurality of optical heads with the remaining targets of the plurality of targets. Having one fixed optical head may simplify the process of aligning the plurality of optical heads with the plurality of targets.

In some embodiments, after performing step 240, the stage may move the workpiece along the X-axis or the Y-axis to align the plurality of optical heads with a different region of interest of the workpiece containing different targets. Accordingly, steps 210 to 240 may be repeated for each region of interest of the workpiece to capture images of each of the plurality of targets of the workpiece.

With the method 200, multiple optical heads can be independently aligned with a plurality of targets of the workpiece in order to perform measurements of multiple targets simultaneously, which improves efficiency and throughput compared a system with a single optical head, and also improves accuracy compared to a system with multiple fixed optical heads.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a stage configured to support a workpiece, wherein a plurality of targets are defined on a surface of the workpiece;
a plurality of optical heads arranged above the stage, wherein each optical head comprises a camera configured to capture a first image of one of the plurality of targets positioned along an optical axis of the camera and a motion mechanism configured to translate the optical head along three axes relative to the stage and rotate the optical head along two axes that are orthogonal to the optical axis; and
a processor in electronic communication with the camera and the motion mechanism of each optical head, wherein for each optical head, the processor is configured to:
receive the first image of a target captured by the camera;
determine a corrective movement of the optical head based on a misalignment of the optical axis of the camera relative to the target in the first image; and
send instructions to the motion mechanism to move the optical head according to the corrective movement to align the optical axis with the target, such that the plurality of optical heads are each independently aligned with one the plurality of targets of the workpiece.

2. The system of claim 1, wherein for each optical head, the misalignment of the optical axis of the camera relative to the target comprises at least one of a translational misalignment, an angular misalignment, or a focus misalignment.

3. The system of claim 2, wherein for each optical head, the corrective movement comprises a translation of the optical head to center the optical axis with a center of the target to correct for the translational misalignment.

4. The system of claim 2, wherein for each optical head, the corrective movement comprises a rotation of the optical head to position the optical axis to be orthogonal to the target on the surface of the workpiece to correct for the angular misalignment.

5. The system of claim 2, wherein each optical head further comprises an objective lens disposed in the optical axis, and the motion mechanism of each optical head comprises a linear actuator configured to translate the objective lens along the optical axis relative to the camera to adjust a focus of the camera with the target.

6. The system of claim 5, wherein for each optical head, the corrective movement comprises a translation of the objective lens to correct for the focus misalignment.

7. The system of claim 1, wherein the motion mechanism of each optical head comprises:
four X-linear bearings, including two upper X-linear bearings connected to an upper end of the optical head and two lower X-linear bearings connected to a lower end of the optical head;
an X-linear actuator connected a rear end of the optical head by an X-rotary bearing, wherein the X-linear actuator is configured to translate the optical head along an X axis guided by the four X-linear bearings;
four Z-linear actuators, including two upper Z-linear actuators connected to the two upper X-linear bearings by two upper rotary bearings and two lower Z-linear actuators connected to the two lower X-linear bearings by two lower rotary bearings, wherein cooperative movement of the two upper Z-linear actuators and the two lower Z-linear actuators is configured to translate the optical head along a Z axis, and opposing movement of the two upper Z-linear actuators and the two lower Z-linear actuators is configured to rotate the optical head about a pitch axis;
four Y-linear bearings, including two upper Y-linear bearings connected to the two upper Z-linear actuators and two lower Y-linear bearings connected to the two lower Z-linear actuators; and
two Y-linear motors, including an upper Y-linear motor connected to the two upper Y-linear bearings and a lower Y-linear motor connected to the two lower Y-linear bearings, wherein cooperative movement of the two Y-linear motors is configured to translate the optical head along a Y axis guided by the four Y-linear bearings, and opposing movement of the two Y-linear motors is configured to rotate the optical head about a roll axis.

8. The system of claim 7, further comprising:
an upper support arranged above the plurality of optical heads, wherein the two upper Y-linear bearings and the upper Y-linear motor of each motion mechanism are connected to the upper support;
a lower support arranged below the plurality of optical heads, wherein the two lower Y-linear bearings and the lower Y-linear motor of each motion mechanism are connected to the lower support; and
a vertical support connected to the upper support and the lower support, wherein the X-linear actuator is connected to the vertical support.

9. The system of claim 1, wherein the motion mechanism of each optical head further comprises:
one or more linear encoders;
wherein the processor is further configured to:
receive position signals from the one or more linear encoders from each of the plurality of optical heads;
determine relative locations of the plurality of optical heads based on the position signals; and
determine the corrective movement of each optical head based on the misalignment of the optical axis of the camera of the optical head relative to the target and the relative locations of the plurality of optical heads.

10. The system of claim 1, wherein the plurality of optical heads are arranged in a one-dimensional array above the stage.

11. The system of claim 1, wherein the plurality of optical heads are arranged in a two-dimensional array above the stage.

12. The system of claim 1, wherein after the plurality of optical heads are independently aligned with the plurality of targets of the workpiece, the processor is further configured to send instructions to the camera of each optical head to simultaneously capture a plurality of second images of the plurality of targets.

13. The system of claim 1, wherein the plurality of optical heads includes one fixed optical head and a plurality of movable optical heads, the stage is further configured to move the workpiece relative to the one fixed optical head, and the processor is further configured to:
send instructions to the stage to move relative to the one fixed optical head to align the optical axis with one target, while the plurality of movable optical heads are independently aligned with remaining targets of the workpiece.

14. The system of claim 13, wherein the one fixed optical head further comprises an objective lens disposed in the optical axis, and the motion mechanism of the one fixed optical head comprises a linear actuator configured to translate the objective lens relative to the camera along the optical axis to adjust a focus of the camera with the target.

15. A method comprising:
A) capturing, with cameras of a plurality of optical heads, a plurality of first images of a plurality of targets defined on a surface of a workpiece supported by a stage, wherein each first image includes a target of the plurality of targets positioned along an optical axis of a camera of one of the plurality of optical heads;
B) determining, with a processor, a corrective movement of one optical head based on a misalignment of the optical axis of the camera of the optical head relative to the target in one of the plurality of first images;
C) moving, with a motion mechanism, the optical head according to the corrective movement to align the optical axis with the target, wherein the motion mechanism is configured to translate the optical head along three axes relative to the stage and rotate the optical head along two axes that are orthogonal to the optical axis; and
D) repeating steps B) and C) for each of the plurality of optical heads, such that the plurality of optical heads are each independently aligned with one of the plurality of targets of the workpiece.

16. The method of claim 15, wherein step B) comprises:
determining whether the misalignment of the optical axis of the camera of the optical head relative to the target comprises at least one of a translational misalignment, an angular misalignment, or a focus misalignment; and
determining the corrective movement of the optical head to correct for at least one of the translational misalignment, the angular misalignment, or the focus misalignment.

17. The method of claim 16, wherein step C) comprises at least one of:
translating the optical head to center the optical axis with a center of the target to correct for the translational misalignment;
rotating the optical head to position the optical axis to be orthogonal to the target on the surface of the workpiece to correct for the angular misalignment; or
translating an objective lens of the optical head along the optical axis relative to the camera to correct for the focus misalignment.

18. The method of claim 15, wherein step B) comprises:
receiving position signals from one or more linear encoders from each of the plurality of optical heads;
determining relative locations of the plurality of optical heads based on the position signals; and
determining the corrective movement of the optical head based on a misalignment of the optical axis of the camera of the optical head relative to the target and the relative locations of the plurality of optical heads.

19. The method of claim 15, wherein the plurality of optical heads includes one fixed optical head and plurality of movable optical heads, and before step B), the method further comprises:
moving the stage relative to the one fixed optical head to align the one fixed optical head with one target;
wherein the steps B) to D) are performed to independently align the plurality of movable optical heads with remaining targets of the workpiece.

20. The method of claim 15, further comprising:
E) simultaneously capturing, with the cameras of the plurality of optical heads, a plurality of second images of the plurality of targets.
